(19) United States
(12) Patent Application Publication
(10) Pub. No.: US 2026/0010697 A1
(43) Pub. Date: Jan. 8, 2026

(54) SIMULATION APPARATUS, PROGRAM, AND SIMULATION METHOD

(71) Applicant: ROHM CO., LTD., Kyoto-shi (JP)

(72) Inventor: Kenji HAMACHI, Kyoto-shi (JP)

(21) Appl. No.: 19/257,637

(22) Filed: Jul. 2, 2025

(30) Foreign Application Priority Data
Jul. 3, 2024 (JP) 2024-107503

(51) Int. Cl. G06F 30/3308; G06F 30/20

(52) U.S. Cl. CPC G06F 30/3308; G06F 30/20

(57) ABSTRACT

The simulation apparatus includes a model storage unit in which a motor physical model derived from modeling of a brushed motor has been stored, and a model computing unit configured to execute computing process by using the motor physical model. The motor physical model includes a winding circuit portion derived from modeling of permanent magnets, windings, commutator segments connected to the windings, and brushes contactable with the commutator segments, all of which are of the brushed motor.

The present invention claims priority under 35 U.S.C. § 119 to Japanese Application No. 2024-107503 filed on Jul. 3, 2024, the entire contents of which are hereby incorporated by reference.

### BACKGROUND OF THE INVENTION

### 1. Field of the Invention

The present disclosure relates to a simulation apparatus.

Conventionally, there has been known a brushed DC (Direct Current) motor (hereinafter, referred to as BDC motor) including brushes and a commutator (e.g., Japanese Patent Laid-Open Publication No. 2015-56913).

### BRIEF DESCRIPTION OF THE DRAWINGS

FIG. 1 is a diagram showing the configuration of a computer according to an exemplary embodiment of the present disclosure.

FIG. 2 is a diagram showing the configuration of a simulation apparatus according to the exemplary embodiment of the disclosure.

FIG. 3 includes a side view (left part) and a front view (right part) showing a schematic configuration example of a BDC motor.

FIG. 4 is a schematic cross-sectional plan view showing a configuration example of the BDC motor.

FIG. 5 is a developed view of the configuration shown in FIG. 4, as it is circumferentially developed.

FIG. 6 is a view showing a configuration of a motor physical model.

FIG. 7 is a chart showing one example of a plot of a counter-electromotive-voltage constant versus rotational speed.

FIG. 8 includes charts showing one example of plots of motor terminal current, counter-electromotive-voltage constant, and motor torque versus rotational speed.

FIG. 9 is a view showing model parameters of the motor physical model.

FIG. 10 is a view showing a gap between commutator segments.

FIG. 11 is a view for use in explaining contact resistance between commutator segments and a brush.

FIG. 12 is a view showing rotational movement of sides of windings.

FIG. 13 is a chart showing one example of magnetic flux density distributions.

FIG. 14 is a view showing a displacement between permanent magnets and the brushes.

FIG. 15 is a view showing a length of one side of a winding.

FIG. 16 is a view showing a distance of one side of the winding from a rotational axis.

FIG. 17 is a diagram showing a filter configuration in a vicinity of a motor terminal.

FIG. 18 includes a plan view, a perspective view, and a developed view each schematically showing rotational movement of the winding.

FIG. 19 is a schematic developed view showing rotational movement of the winding.

FIG. 20 is a view showing an overall image of a winding circuit portion.

FIG. 21 is a table showing a calculation method for contact resistance.

FIG. 22 is a diagram showing a configuration of a motor physical model in a case where modeling is executed by Simscape (trademark)/Simulink (trademark).

FIG. 23 is a diagram showing a partial configuration of the winding circuit model portion.

FIG. 24 is a chart showing one example of simulation results.

FIG. 25 is a chart showing one example of comparisons between simulation and actual apparatus.

### DETAILED DESCRIPTION OF PREFERRED EMBODIMENTS

Hereinafter, an exemplary embodiment of the present disclosure will be described with reference to accompanying drawings.

### <Configuration of Computer>

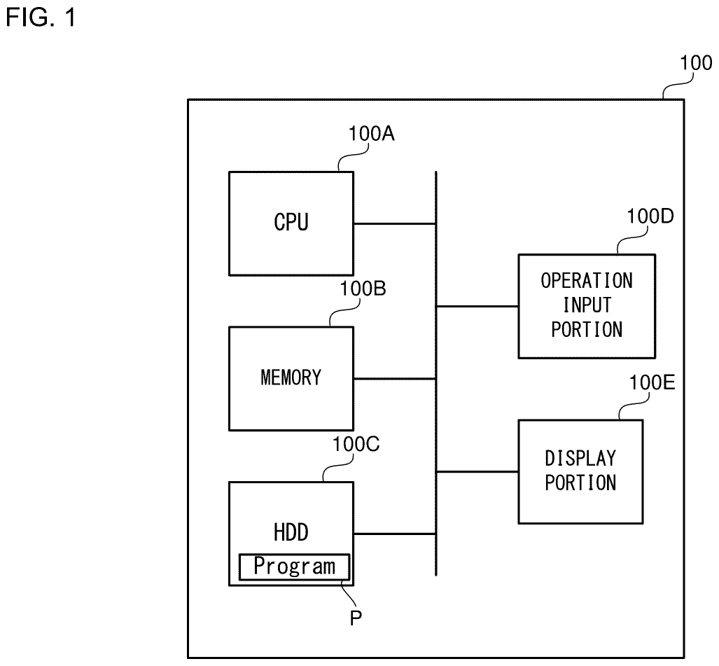

FIG. 1 is a diagram showing the configuration of a computer 100 according to an exemplary embodiment of the present disclosure. The computer 100 functions as a later-described simulation apparatus according to the present disclosure. The computer 100 is, for example, a PC (personal computer). It is no matter whether the PC is desktop type or notebook type.

The computer 100 includes a CPU (Central Processing Unit) 100A, a memory 100B, an auxiliary storage device 100C, an operation input portion 100D, and a display portion 100E.

The CPU 100A includes a control device and a computation device (neither is shown). The control device interprets instructions in a program to control the different parts of the computer 100. The computation device executes arithmetic operations.

The memory 100B is a semiconductor storage device that temporarily stores a program or data. The information stored in the memory 100B is lost when the power to the computer 100 is turned off.

The auxiliary storage device 100C is configured with an HDD (hard disk drive), an SSD (solid-state drive), or the like and stores a program or data. The program stored in the auxiliary storage device 100C is read into the memory 100B. The CPU 100A executes the program read into the memory 100B.

The operation input portion 100D is configured with a keyboard, a mouse, and the like and feeds the computer 100 with the input of user operations. The information input through the operation input portion 100D is fed to the memory 100B.

The display portion 100E is configured with, for example, a liquid crystal display and outputs the information acquired from the memory 100B in a form converted into an image.

### <Configuration of Simulation Apparatus>

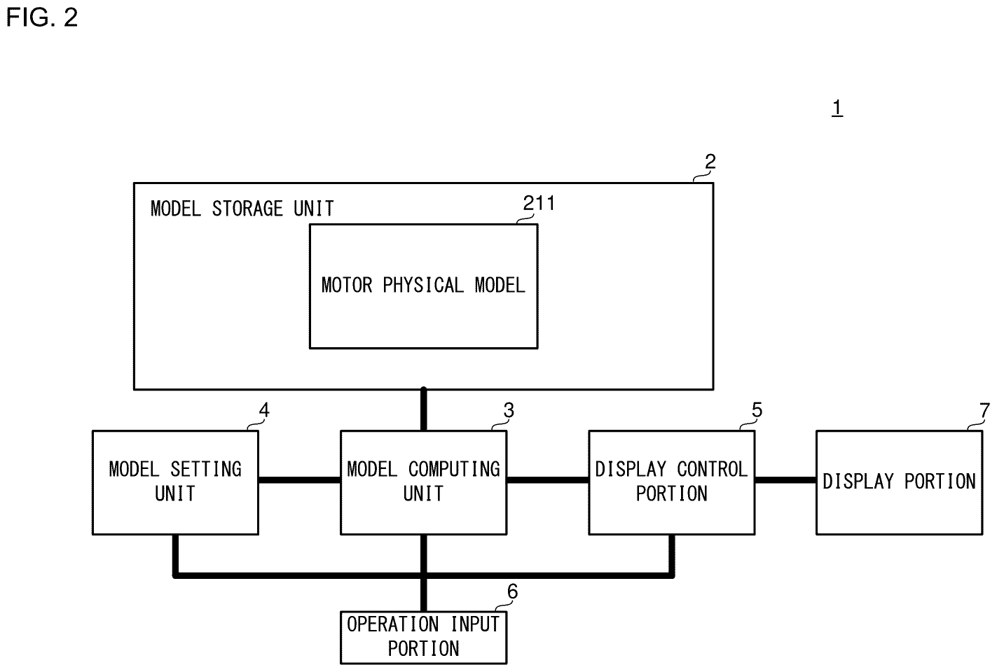

FIG. 2 is a diagram showing the configuration of a simulation apparatus 1 according to the exemplary embodiment of the disclosure. The simulation apparatus 1 includes a model storage unit 2, a model computing unit 3, a model setting unit 4, a display control portion 5, an operation input portion 6, and a display portion 7. A program P (FIG. 1) stored in the auxiliary storage device 100C of the computer 100 is a program arranged to make the computer 100 function as the simulation apparatus 1.

The model storage unit 2, having stored a motor physical model 211, consists of the auxiliary storage device 100C of the computer 100. The motor physical model 211 is constructed as a program P by MATLAB (trademark)/Simulink (trademark) as an example. The motor physical model 211 is a model obtained by modeling a BDC motor, which will be detailed later.

Individual functions of the model computing unit 3, the model setting unit 4, and the display control portion 5 are implemented by the CPU 100A executing the program P. In addition, the operation input portion 6 and the display portion 7 are equivalent to the operation input portion 100D and the display portion 100E, respectively, of the computer 100.

The model computing unit 3 executes computing process of the motor physical model 211 stored in the model storage unit 2 to implement simulation. The model setting unit 4 executes settings related to the motor physical model 211 (setting of parameters etc.) in response to inputs from the operation input portion 6. Simulations by the model computing unit 3 are executed according to setting contents by the model setting unit 4. The display control portion 5 executes control for display of a model setting screen on the display portion 7 in response to inputs from the operation input portion 6, or control for display of simulation results on the display portion 7, and the like.

### <Motor Physical Model>

Here is explained about the motor physical model 211. The motor physical model 211 is a model derived from modeling of logics of internal structure of the BDC motor as well as physics of the rotational principle.

### <<Structure of Motor>>

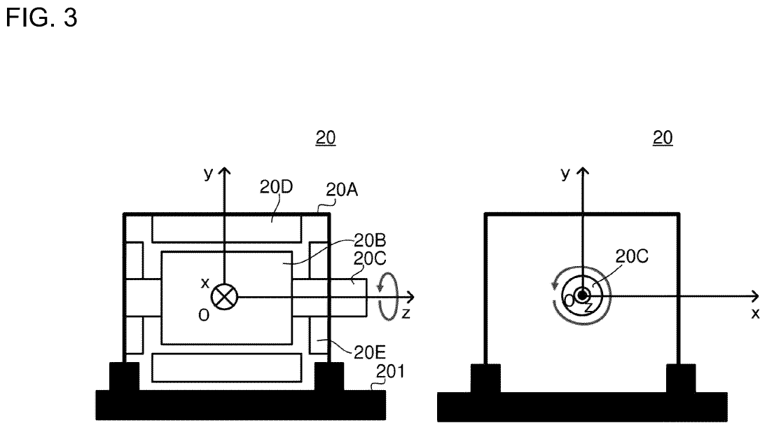

FIG. 3 includes a side view (left part) and a front view (right part) showing a schematic configuration example of a motor 20, which is a BDC motor. It is noted that the orthogonal coordinate system shown in FIG. 3 is a rest frame system fixed on a base 201. The X axis, the Y axis, and the Z axis are orthogonal to one another. The Z axis is so positioned as to extend in a direction in which a shaft 20C extends, and as to pass through a center of the shaft 20C. The Y axis is so positioned as to extend perpendicular to a plane of the base 201. The X axis is so positioned as to extend parallel to the plane and in a horizontal direction. In FIG. 3, for example, an origin O of the orthogonal coordinate system is included in a rotor 20B.

As shown in FIG. 3, the motor 20 is fixed on the base 201. The motor 20 includes a casing 20A, a rotor 20B, a shaft 20C, a stator 20D, and bearings 20E. The rotor 20B, the shaft 20C, the stator 20D, and the bearings 20E are contained inside the casing 20A. The stator 20D, which is fixed to the casing 20A, does not rotate. The rotor 20B, which is placed on an inner circumferential side of the stator 20D, is rotatable relative to the stator 20D. The shaft 20C protrudes on both sides of the rotational-axis direction (Z axis direction) from the rotor 20B. The shaft 20C is rotatably supported by the bearings 20E on both sides of the rotational-axis direction, respectively. The bearings 20E are fixed to the casing 20A. In addition, although the motor 20 is an inner rotor type one in which the rotor 20B is positioned on the inner circumferential side of the stator 20D in FIG. 3, yet the motor 20 may instead be an outer rotor type one in which the rotor is positioned on the outer circumferential side of the stator.

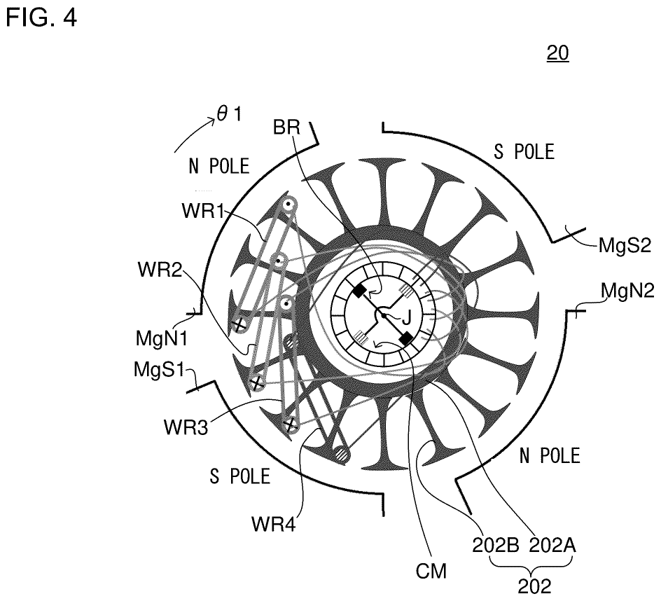

FIG. 4 is a schematic cross-sectional plan view showing a configuration example of the motor 20. FIG. 4 is a view as viewed along a rotational axis J direction. The rotational axis J is congruous with the Z axis. Hereinafter, a direction in which the rotational axis J extends will be referred to as axial direction, a direction around the rotational axis J will be referred to as circumferential direction, and a direction perpendicular to the rotational axis J will be referred to as radial direction.

The stator 20D includes a permanent magnet Mg and a brush BR. In the configuration of FIG. 4, the permanent magnet Mg includes magnets MgS1, MgN1, MgS2 and MgN2. The magnets MgS1, MgN1, MgS2 and MgN2 cause S pole, N pole, S pole and N pole to be placed circumferentially on the radially inner side. That is, the magnetic poles of S pole and N pole are alternately placed circumferentially on the radially inner side.

The brush BR includes an anode brush and a cathode brush as will be described later. Polarities of the brush are alternately placed along the circumferential direction.

The rotor 20B includes an iron core 202, windings WR, and commutator segments CM. The iron core 202 is made up, for example, by stacking electromagnetic steel sheets in the axial direction. The iron core 202 is placed on the radially inner side of the permanent magnet Mg. The iron core 202 includes an annular portion 202A and teeth 202B. The annular portion 202A extends in the axial direction to form a circumferentially annular shape. The teeth 202B protrude from the outer circumferential surface of the annular portion 202A toward the radially outer side. The teeth 202B are arrayed in plurality along the circumferential direction.

The windings WR in the configuration of FIG. 4 include 16 windings of windings WR1 to WR16. In FIG. 4, typically, windings WR1 to WR4 only are depicted. Each winding WR is wound on the teeth 202B so as to pass through between a circumferential one-side portion (depicted as θ1) of one tooth 202B and a circumferential other-side portion of the second-neighboring tooth 202B as counted from the one tooth 202B in the reverse circumferential direction. The teeth 202B to be wound with the windings WR are alternately displaced by one tooth 202B from each other in the circumferential direction. Thus, the configuration of FIG. 4 is a concentrated-winding configuration.

The commutator segments CM are placed radially inside of the iron core 202 and radially outside of the brush BR. In the configuration of FIG. 4, the commutator segments CM include commutator segments CM1 to CM16 (signs are not shown in FIG. 4), i.e., sixteen commutator segments. The commutator segments CM1 to CM16 are placed in a circumferentially annular shape. One and the other lead wires derived from each winding WR are connected to each of circumferentially-neighboring commutator segments CM, respectively. Commutator segments CM to be connected to each other with those windings WR are each displaced on a one-commutator-segment CM basis.

Each commutator segment CM is contactable with the brush BR. Rotation of the rotor 20B causes the commutator segments CM to rotate, where it is variable with time which commutator segment CM is brought into contact with the brush BR, as well as how much the contact resistance therebetween is.

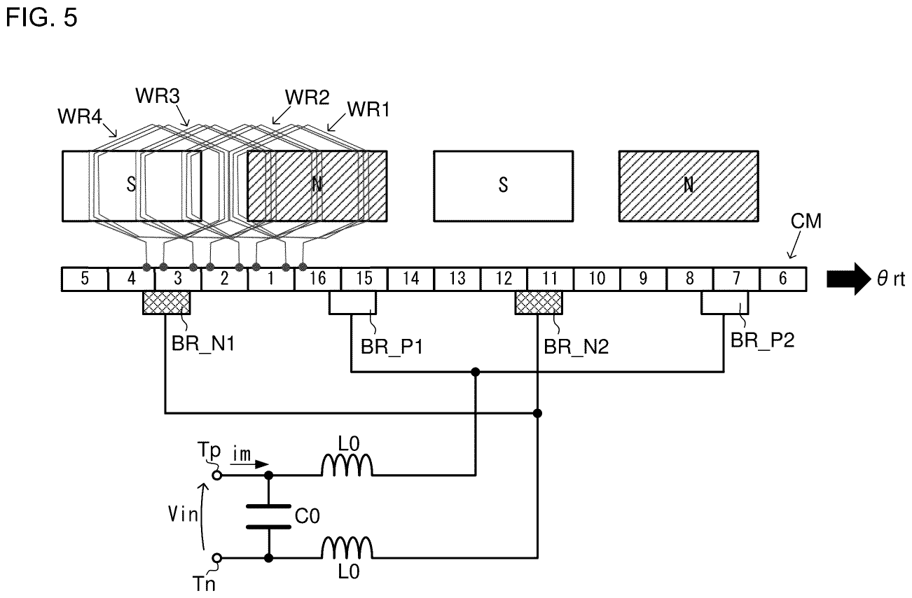

FIG. 5 is a developed view of the configuration shown in FIG. 4, as it is circumferentially developed. FIG. 5 shows a rotational direction θrt of the rotor 20B. The rotational direction θrt is identical in direction to the circumferential one-side direction θ1 shown in FIG. 4. S poles and N poles are placed along the rotational direction θrt. Also, the commutator segments CM1 to CM16 are placed along the rotational direction θrt. More specifically, along the rotational direction θrt, the commutator segments CM16 to CM15 to . . . are arrayed in this order; after reaching the commutator segment CM1, the array of the commutator segments is returned to the commutator segment CM16. That is, the commutator segments CM are placed in a loop along the rotational direction θrt.

As described above, one and the other of lead wires derived from the windings WR are connected to circumferentially-neighboring commutator segments CM, respectively. More specifically, as shown in FIG. 5, one of the lead wires derived from the winding WR1 is connected to the commutator segment CM16, while the other is connected to the commutator segment CM1. One of the lead wires derived from the winding WR2 is connected to the commutator segment CM1, while the other is connected to the commutator segment CM2. One of the lead wires derived from the winding WR3 is connected to the commutator segment CM2, while the other is connected to the commutator segment CM3. One of the lead wires derived from the winding WR4 is connected to the commutator segment CM3, while the other is connected to the commutator segment CM4. Similarly, the windings of up to WR16 are connected to the commutator segments CM. It is noted that in FIG. 5, only the windings WR1 to WR4 are depicted typically. As a result of this, the windings WR are connected in series via the commutator segments CM to form a loop circuit.

The brush BR includes anode brushes BR_P1, BR_P2, and cathode brushes BR_N1, BR_N2. The cathode brush BR_N1, the anode brush BR_P1, the cathode brush BR_N2, and the anode brush BR_P2 are placed in this order along the rotational direction θrt.

Rotation of the rotor 20B causes the commutator segments CM1 to CM16 to be moved in the rotational direction θrt, followed by changeover of the commutator segment CM that contacts with the anode brushes BR_P1, BR_P2 and the cathode brushes BR_N1, BR_N2 in succession. FIG. 5 shows, as an example, a state in which the commutator segments CM4, CM3 are in contact with the cathode brush BR_N1, the commutator segments CM16, CM15 are in contact with the anode brush BR_P1, the commutator segments CM12, CM11 are in contact with the cathode brush BR_N2, and the commutator segments CM8, CM7 are in contact with the anode brush BR_P2. The windings WR are moved along the rotational direction θrt together with the commutator segments CM to cross magnetic flux formed by magnetic poles.

### <<Overall Configuration of Motor Physical Model>>

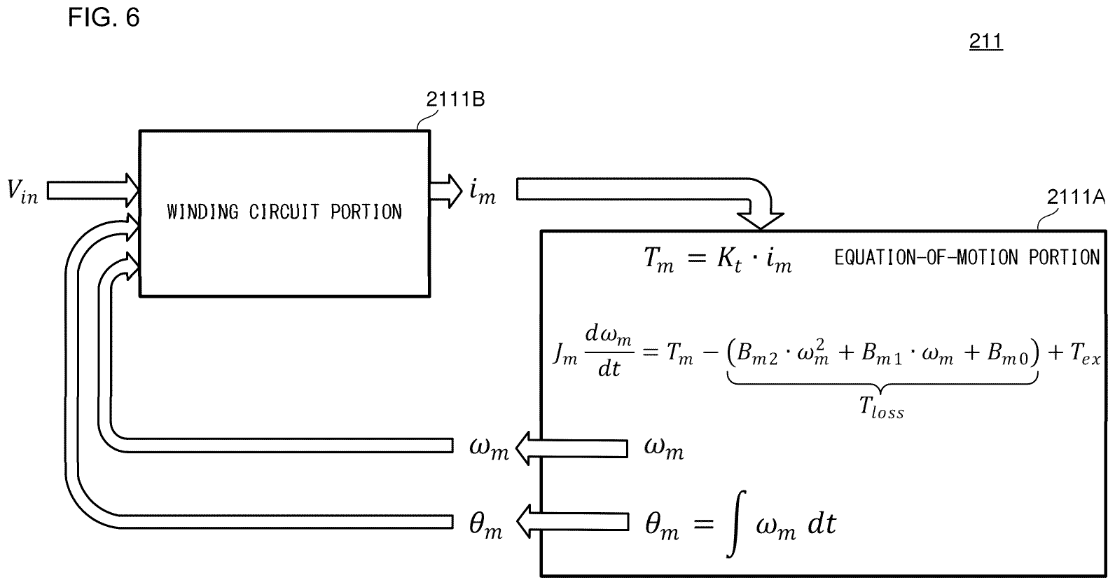

FIG. 6 is a view showing a configuration of the motor physical model 211. The motor physical model 211 includes an equation-of-motion portion 2111A, and a winding circuit portion 2111B.

FIG. 6 is a diagram showing an input/output relation between the equation-of-motion portion 2111A and the winding circuit portion 2111B. When an input voltage Vin is inputted to the winding circuit portion 2111B, a motor terminal current im is calculated and outputted. It is noted that the input voltage Vin is applied to between a motor anode terminal Tp and a motor cathode terminal Tn as shown in FIG. 5, while the motor terminal current im is a current flowing through a motor terminal. The motor terminal current im is inputted to the equation-of-motion portion 2111A, and a mechanical-angle angular velocity ωm and a mechanical angle θm of the rotor 20B are calculated and outputted. The mechanical-angle angular velocity ωm and the mechanical angle θm are fed back to the winding circuit portion 2111B.

### <<On Equation-of-Motion Portion>>

The equation-of-motion portion 2111A has, as an equation of motion, Expression (1) below:

$${J}_{m} \frac{d {ω}_{m}}{d t} = {T}_{m} - ( {B}_{m 2} \cdot {ω}_{m}^{2} + {B}_{m 1} \cdot {ω}_{m} + {B}_{m 0} ) + {T}_{e x} \qquad ( 1 )$$

where Jm is an inertia of the rotating portion (rotor 20B and shaft 20C) of the motor 20, Tm is a motor torque, and Tex is an external torque.

The motor torque Tm is given by Expression (2) below.

$${T}_{m} = {K}_{t} \cdot {i}_{m} \qquad ( 2 )$$

where Kt is a torque constant.

As to motors, a torque is generated by action of a magnetic flux distribution of permanent magnets and a magnetic flux distribution of winding currents. Contribution of the magnetic flux distribution of permanent magnets to the torque depends on shape and placement of magnetic poles as well as geometric placement relation of the windings, independent of the rotational speed and the value of the motor terminal current, hence a constant gain-like contribution. Therefore, as expressed by foregoing Expression (2), the motor torque Tm results in a product of the torque constant Kt as a constant coefficient and the motor terminal current im.

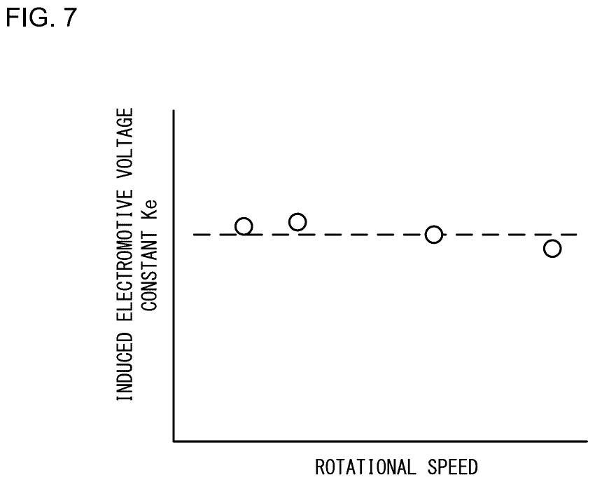

Also, the torque constant Kt has a relationship of Kt=Ke with the counter-electromotive-voltage constant Ke, while a counter electromotive voltage Vbemf and the mechanical-angle angular velocity ωm have a relationship of Vbemf=Ke·ωm. The counter electromotive voltage is a voltage generated across a motor terminal of a motor, which is an object of modeling, under a condition that with the modeling-object motor having its shaft connected to another motor, the shaft is put into constant-speed rotation by the another motor. While the rotational speed was varied, the counter electromotive voltage Vbemf was measured, and Ke=Vbemf/ωm was calculated. As a result, as shown in FIG. 7, the counter-electromotive-voltage constant showed a generally constant result independently of the rotational speed. Therefore, the counter-electromotive-voltage constant was able to be regarded as a constant, where an average value of plotted counter-electromotive-voltage constants was taken as the counter-electromotive-voltage constant Ke. It is also appropriate to set this value as a value of the torque constant Kt. Thus, the counter-electromotive-voltage constant Ke is a constant, which serves as a basis for the foregoing Expression (2).

Referring now to the above-described equation of motion of Expression (1), its left-hand side represents a product of the inertia Jm and a mechanical-angle angular acceleration, while its right-hand side represents a synthetic torque of a motor torque Tm due to application of the input voltage Vin to the motor terminal, a loss torque Tloss comprehensively representing various losses, and an external torque Tex. The external torque Tex is compatible with torques outputted from a load model, torques outputted from a person or an environment, and the like.

The loss torque Tloss is expressed as

$${B}_{m 2} \cdot {ω}_{m}^{2} + {B}_{m 1} \cdot {ω}_{m} + {B}_{m 0} .$$

where Bₘ₀, Bₘ₁ and Bₘ₂ represent loss factors.

As described above, the loss torque is assumed as a quadratic of the mechanical-angle angular velocity ωm. The assumption of loss torque is determined on the basis that under conditions of a constant rotational speed and no application of external torque, an equation holds: motor torque Tm−loss torque=0, that is,

$${T}_{m} - ( {B}_{m 2} \cdot {ω}_{m}^{2} + {B}_{m 1} \cdot {ω}_{m} + {B}_{m 0} ) = 0 .$$

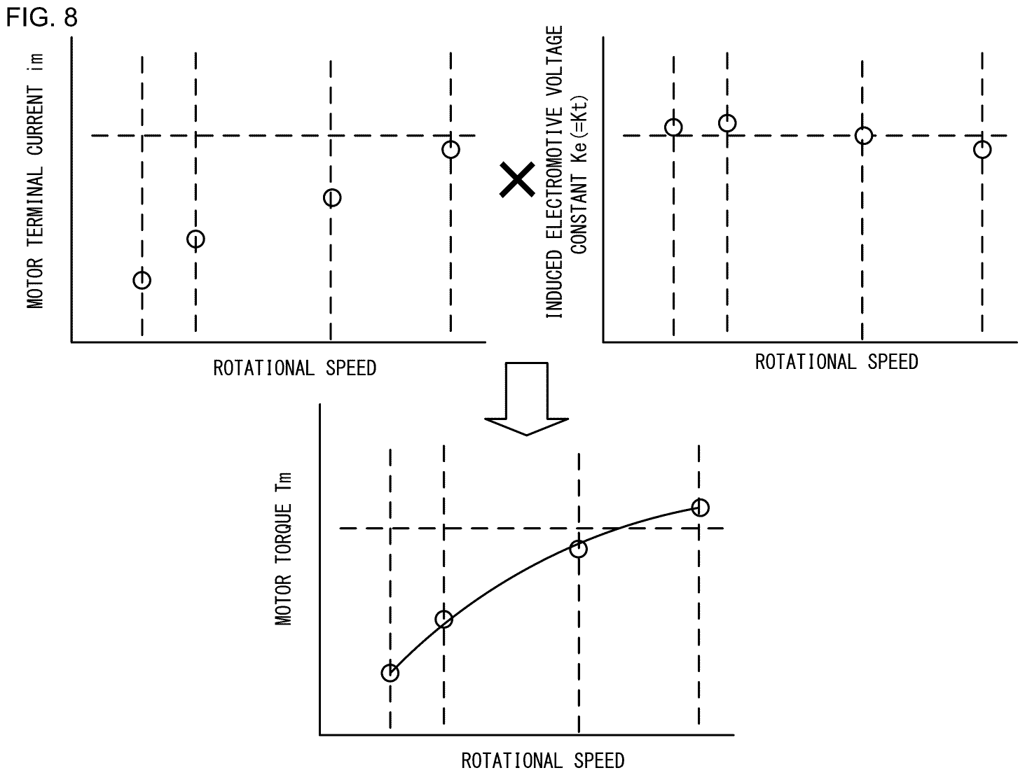

First, average values of motor terminal currents im were measured under a condition that with the rotational speed varied, the input voltage Vin was varied at individual rotational speeds. Measurement results are shown on the upper left hand of FIG. 8. With use of an average value of motor terminal currents and a counter-electromotive-voltage constant Ke (=torque constant Kt) shown in FIG. 7 described before, the motor torque Tm was calculated from Expression (2) above. As shown in FIG. 8, motor torques Tm are obtained on a basis of each rotational speed. Since the motor torque Tm and the loss torque are balanced with each other under constant-speed rotation, the plot of the motor torque Tm shown in FIG. 8 can be regarded as a plot of loss torque. Since regression of the plot shown in FIG. 8 by the quadratic allows a successful coefficient of determination to be obtained, the loss torque was given by a quadratic of the mechanical-angle angular velocity ωm as described above.

### <<On Winding Circuit Portion>>

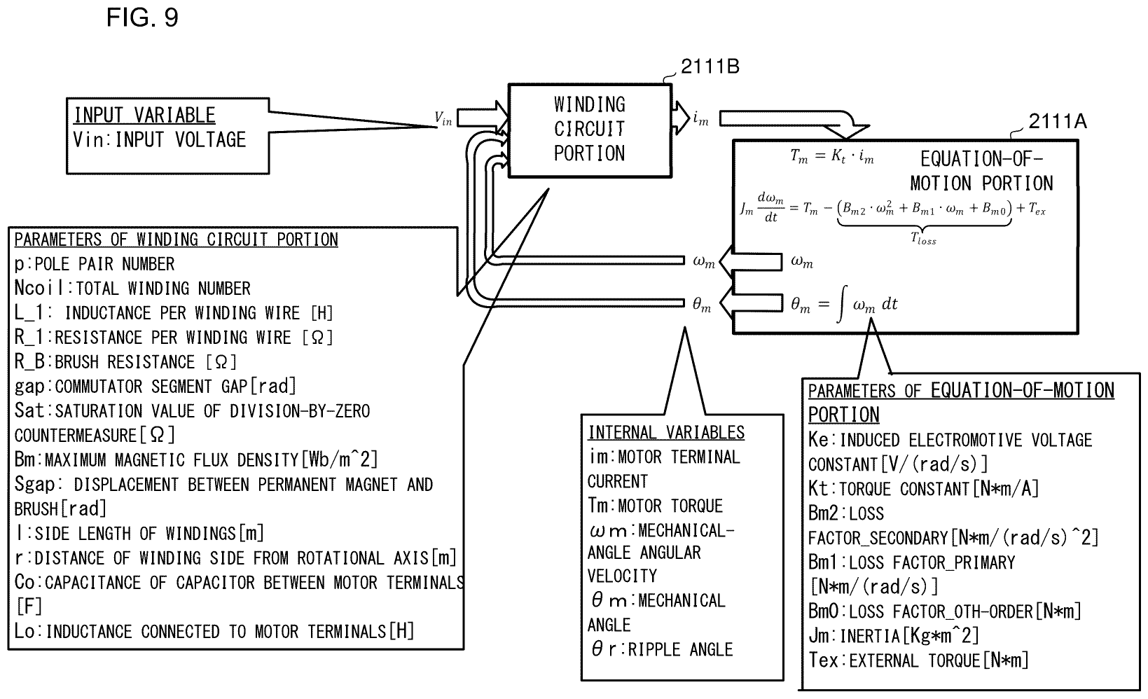

The winding circuit portion 2111B is a model derived from steady modeling of geometric placement of windings WR, permanent magnets Mg, a brush BR, and commutator segments CM in the motor 20. FIG. 9 shows model parameters in the motor physical model 211. Herein below, details of the winding circuit portion 2111B will be described by using parameters in the winding circuit portion 2111B shown in FIG. 9. In addition, also shown in FIG. 9 are the above-described parameters in the equation-of-motion portion 2111A as well as input variables and internal variables in the motor physical model 211. The external torque Tex, although treated as a parameter, may also be treated as an input variable.

A pole pair number p is a number of magnetic pole pairs by permanent magnets Mg. In the configuration of FIG. 5 (FIG. 4), since two pairs of N pole and S pole are included, the pole pair number p=2. A total winding number Ncoil is a total number of windings WR. In the configuration of FIG. 5, the total winding number Ncoil=16.

An inductance L_1 per winding WR, and a resistance R_1 per winding WR can be set, for example in the configuration of FIG. 5, by calculating their values per winding WR, like average values, on a basis of measurements with two parallel circuits of 8-winding series connection at 180-degree symmetrical midpoints of loop circuits by windings WR.

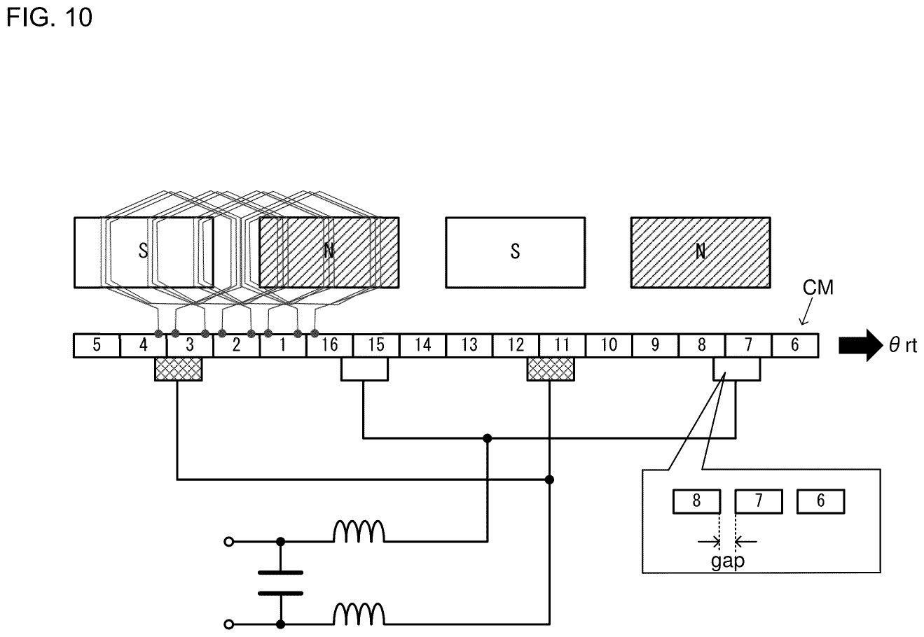

Actually, gaps are present between neighboring commutator segments CM. As shown in FIG. 10, in which gaps between the commutator segments CM are emphasized, a commutator segment gap ‘gap’ is set as a distance of the gap. The commutator segment gap ‘gap’ is set in units ([rad]) of later-described ripple angle θm. The commutator segment gap ‘gap’ is set based on observation results of a real apparatus.

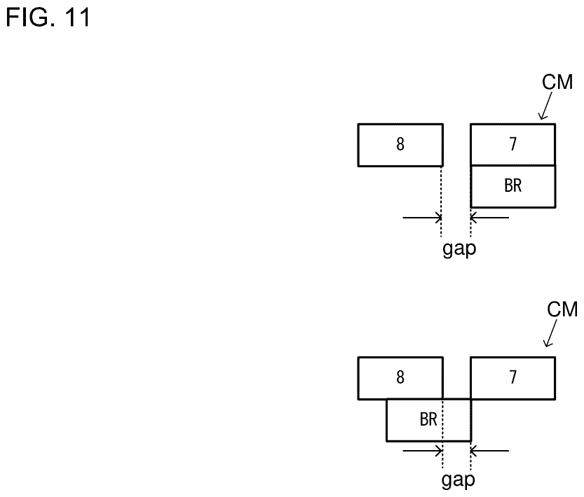

The brush resistance R_B is a contact resistance value under a condition that the brush BR and commutator segments CM have come into contact with each other such that a width of the brush BR and a width of a commutator segment CM just overlap with each other as shown in upper stage of FIG. 11. FIG. 11 shows a case in which the brush BR and the commutator segment CM7 have come into contact with each other, as an example. In such a case, the contact resistance between the commutator segment CM and the brush BR becomes the smallest. The brush resistance R_B is adjusted such that the waveform (ripple waveform) of the motor terminal current im becomes consistent between a real apparatus and a model.

In a case where the brush BR and the commutator segment CM contact with each other at quite a small width, an extreme contact resistance becomes infinite. Shown in the lower stage of FIG. 11 is a state in which the brush BR and the commutator segment CM7 contact with each other at quite a small width, as an example. However, calculation involving infinite is so hard in terms of simulation, and furthermore such an extreme state is considered inexistent from an actual viewpoint. Thus, a saturation value Sat as a countermeasure for division by zero is set as an upper-limit value of the contact resistance. The saturation value Sat is adjusted such that the waveform (ripple waveform) of the motor terminal current im becomes consistent between a real apparatus and the model.

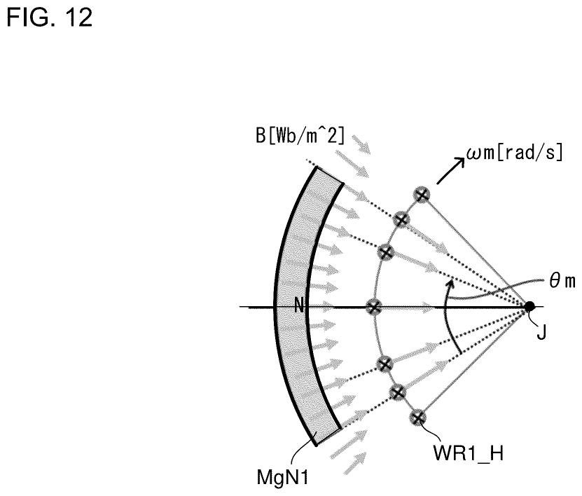

FIG. 12 is a cross-sectional plan view schematically showing movement of a side WR1_H of the winding WR1 around the rotational axis J in a case where the side WR1_H is focused, as well as a magnetic flux density B by the permanent magnet MgN1 (N pole on radially inside). The side WR1_H is a side line extending in the axial direction at an end portion on one side of the winding WR1 opposite to the rotational direction θrt side. As shown in FIG. 12, on the assumption that a state in which the side WR1_H is located on a line segment that connects the rotational axis J and an end portion of the permanent magnet MgN1 on one side opposite to the rotational direction θrt side with each other is defined as mechanical angle θm=0, the magnetic flux density B due to magnetic flux passing through the side WR1_H is determined in response to the mechanical angle θm.

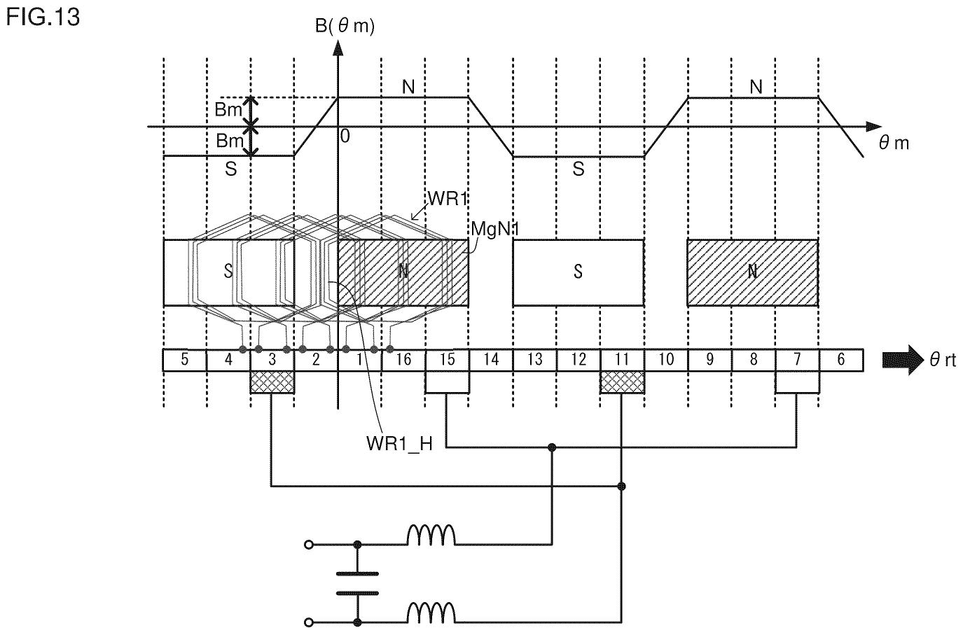

Accordingly, as shown in FIG. 13, a magnetic flux density distribution is set with the magnetic flux density B used as a function B (∂m) of the mechanical angle θm. In this case, a maximum magnetic flux density Bm is set as a parameter, where it is set that B=+Bm for a range in which N poles are placed radially inside while it is set that B=−Bm for a range in which S poles are placed radially inside. In addition, with respect to polarity of the magnetic flux density B, a direction toward the rotational axis J is set as positive as shown in FIG. 12. In ranges between N pole and S pole, the magnetic flux density B is so set as to vary between +Bm and −Bm. In FIG. 13, it is set that B linearly varies between +Bm and −Bm, but the way of variation is not limited to that. The magnetic flux density distribution can be set by the maximum magnetic flux density Bm and equation blocks. In addition, since the windings WR2 to WR16 are determined in their relative position relative to the winding WR1, respectively, the magnetic flux density distribution for a side of each winding corresponding to the side WR1_H is determined in response to the mechanical angle θm.

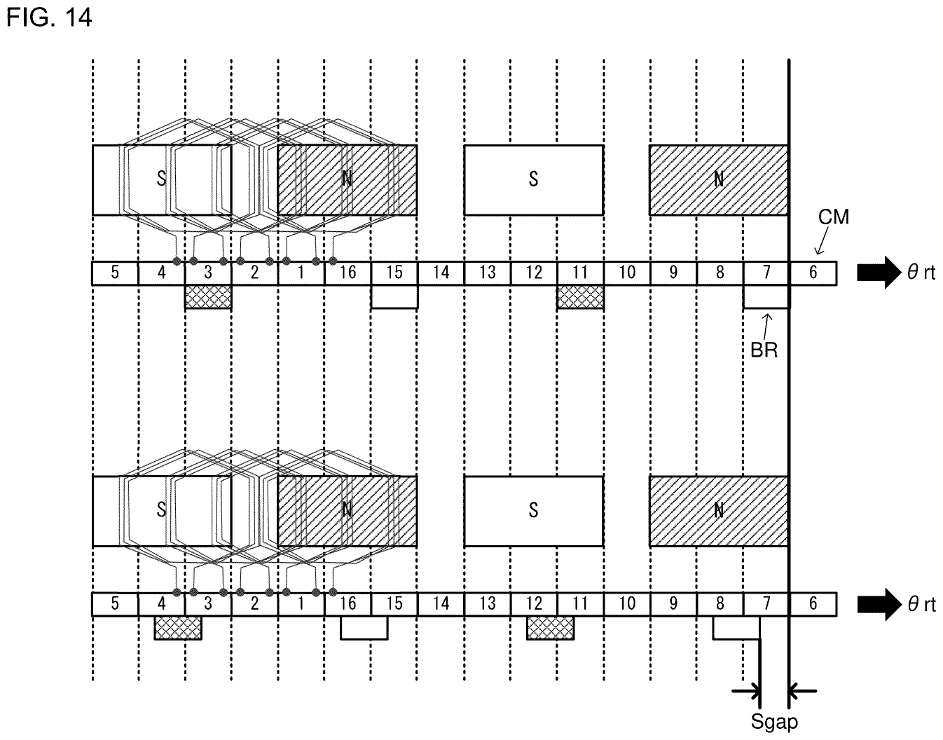

A displacement Sgap (unit: [rad]) is a parameter representing a positional relationship between the magnetic pole of a permanent magnet Mg and the brush BR. In the example shown in FIG. 14, defined is a displacement Sgap resulting when the brush BR is displaced from a reference state (similar to FIG. 13) of the positional relationship between the magnetic poles of permanent magnets Mg and the brush BR shown in the upper stage to another state depicted in the lower stage. In terms of treatment of the displacement Sgap in models, the reference position (origin) of the magnetic flux density distribution is changeable in response to the displacement Sgap. This is because occurrence of any displacement Sgap would cause the magnetic flux density relative to the winding WR to be changed even under a condition of unchanged mechanical angle θm state, i.e., unchanged positional state of the commutator segments CM relative to the brush BR. The displacement Sgap is set based on observation results with a real apparatus.

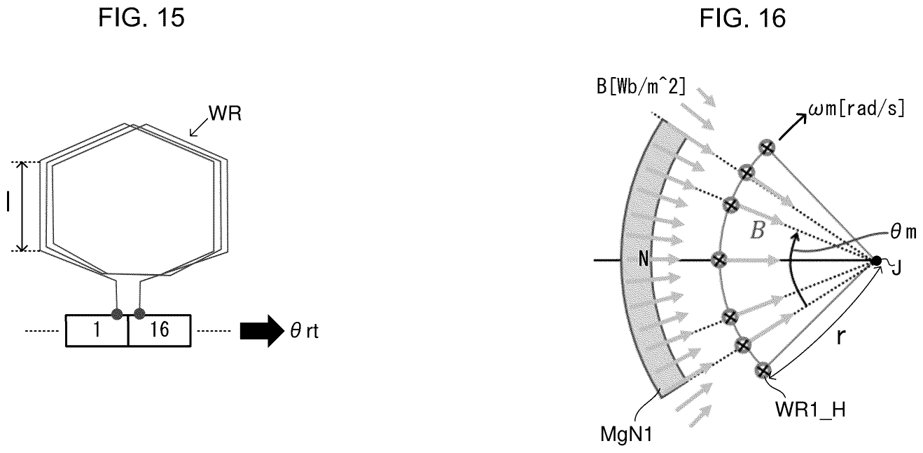

As shown in FIG. 15, a side length 1 of each winding is a parameter representing a length of a side line of a winding WR which extends along the axial direction at one end portion of the rotational direction θrt. The side length 1 of windings is equivalent to the length of the above-described side WR1_H in the case of the winding WR1. The length 1 is set based on observation results with a real apparatus.

A distance r of a side of windings from the rotational axis is a parameter representing a radial distance from the rotational axis J to a side WR_H. FIG. 16 (similar to FIG. 12) shows a distance r corresponding to a side WR1_H of the winding WR1, as an example. The distance r is set based on observation results with a real apparatus.

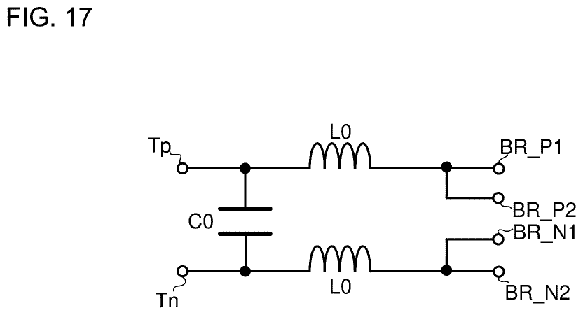

FIG. 17 is a diagram showing a circuit configuration of around a motor terminal (also shown in FIG. 5 or the like). A capacitor C0 is connected between a motor anode terminal Tp and a motor cathode terminal Tn. Inductors L0 are connected to the motor anode terminal Tp and the motor cathode terminal Tn, respectively. The motor anode terminal Tp is connected to an end of one inductor L0, while anode brushes BR_P1, BR_P2 are connected to the other end of the inductor L0. The motor cathode terminal Tn is connected to one end of the other inductor L0, while cathode brushes BR_N1, BR_N2 are connected to the other end of the inductor L0. An LC filter is made up from the capacitor C0 and the inductors L0. The LC filter is used to suppress pulsed noise which is generated upon changeover of the commutator segments CM and the brushes BR. A capacitance value of the capacitor C0 and inductance values of the inductors L0 are set as parameters, respectively.

Next, a description will be given on an induced electromotive voltage generated at windings WR. By the windings WR1 to WR16 crossing magnetic flux of permanent magnets Mg, respectively, an induced electromotive voltage is generated at each of the windings WR1 to WR16. As described above, the magnetic flux density distribution B is set as a function of the mechanical angle θm. By using the set magnetic flux density distribution, induced electromotive voltages are calculated based on time variations of flux linkage with each of the windings WR1 to WR16.

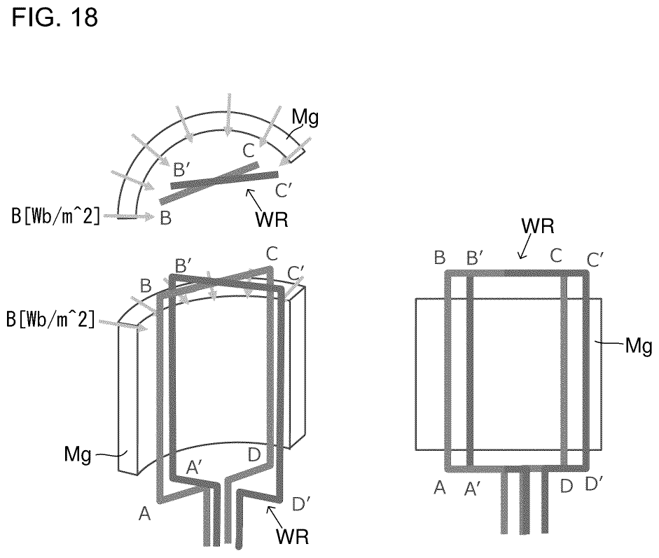

FIG. 18 includes a plan view, a perspective view, and a developed view each schematically showing a state in which one winding WR has been moved by rotation of the rotor 20B. It is assumed that the winding WR has been moved from a state expressed by ABCD to another state expressed by A′B′C′D′.

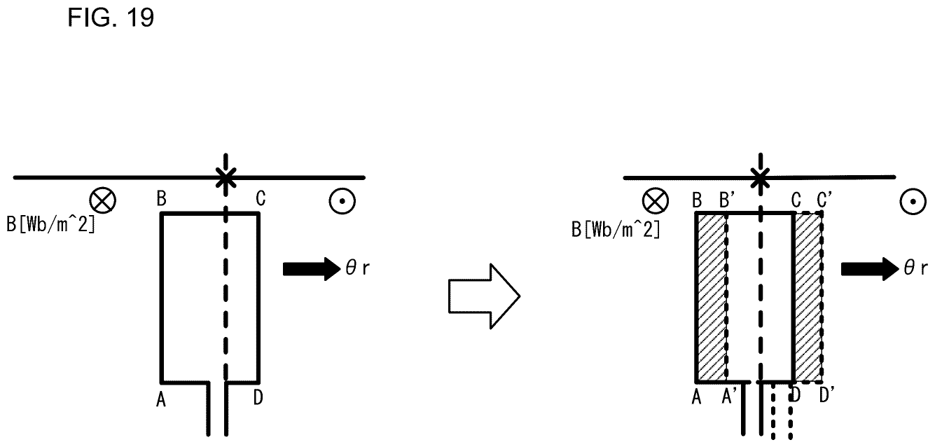

Referring now to a developed view shown in FIG. 19, an area DCC′D′ scanned by a side CD forward of the rotational direction θrt is an area incremented by rotational movement of the winding WR and expressed as a positive area. Meanwhile, an area ABB′A′ scanned by a side BA rearward of the rotational direction θrt is an area decremented by the rotational movement of the winding WR and expressed as a negative area. Also, an area A′B′CD is an area which is unchanged before and after rotational movement, magnetic flux penetrating through this area being also unchanged, so that the area does not contribute to magnetic flux variation Δφ. From the above-described assumptions, the magnetic flux variation Δφ is determined by a product of a signed area and a magnetic flux density passing through the area. Accordingly, the induced electromotive voltage e_{coil,No.} is expressed by the following expression:

$${e}_{coil , No} . = Δφ / Δ t = ( ( magnetic flux density at forward side position ) \times ( scanned area of forward side ) + ( magnetic flux density at rearward side position ) \times ( - ( scanned area of rearward side ) ) ) / Δ t$$

Where, e_{coil,No.} is an induced electromotive voltage generated at a winding represented by No. (winding number) (e.g., WR1 represented by No.=1).

Also, by using the side length 1 of each winding and the side distance r of each winding from the rotational axis, calculations result in the positive area=1·rωm, and the negative area=−1·rωm.

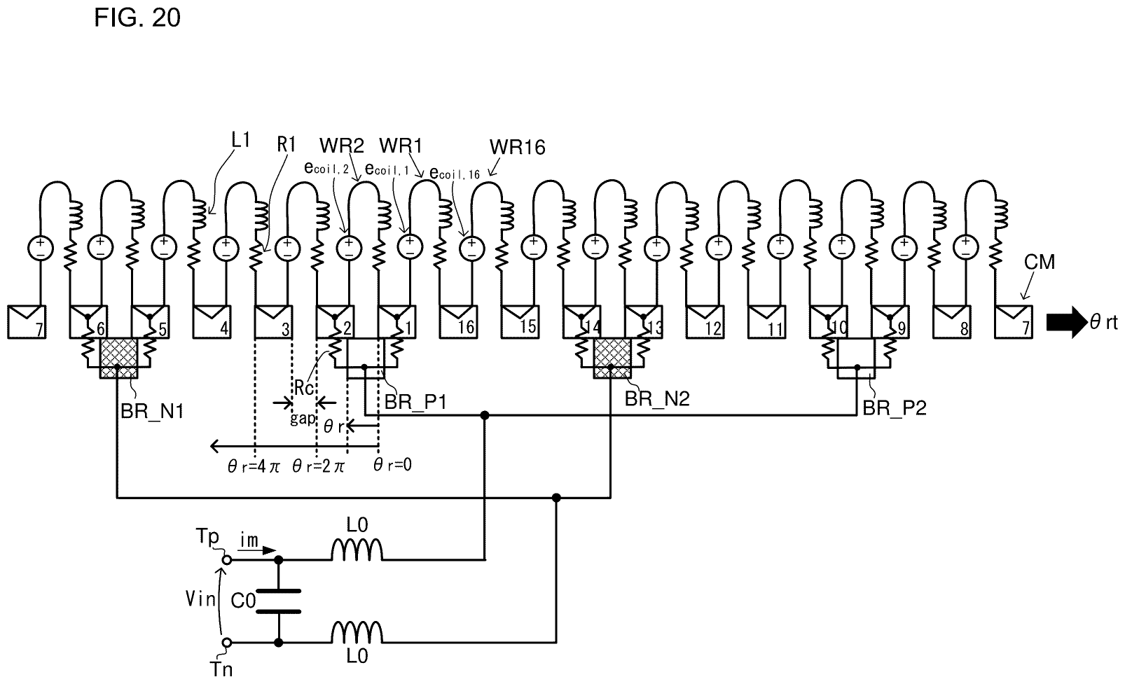

FIG. 20 is a view showing an overall image of the winding circuit portion 2111B. Modeling was executed in such fashion that the induced electromotive voltage e_{coil,No.} would be outputted from a voltage source inserted in series to the inductance L_1 and the resistor R_1 in each of the windings WR1 to WR16.

Further, a description on the ripple angle θr shown in FIG. 20 is given below. On the assumption that a focused brush BR is designated as specified brush (anode brush BR_P1 in FIG. 20) and a focused commutator segment CM is designated as specified commutator segment (commutator segment CM2 in FIG. 20), a contact resistance Rc between the specified brush and the specified commutator segment can be determined as follows.

On the assumption that a commutator segment CM adjoining the specified commutator segment on the rotational direction θrt side is designated as forward commutator segment (commutator segment CM1 in FIG. 20) and a commutator segment CM adjoining the specified commutator segment on the side opposite to the rotational-direction θrt side is designated as rearward commutator segment (commutator segment CM3 in FIG. 20), a state in which a rearward end portion of the specified brush overlaps with a rearward end portion of the forward commutator segment (a state in which a width of the specified brush and a width of the forward commutator segment are just equal to each other) is set as ripple angle θr=0, and a distance from the rearward end portion of the forward commutator segment to the rearward end portion of the specified brush is expressed as ripple angle θr [rad]. In a state in which the rearward end portion of the specified brush overlaps with the rearward end portion of the specified commutator segment (a state in which the width of the specified brush and the width of the specified commutator segment are just equal to each other), it holds that ripple angle θr=2pi. In a state in which the rearward end portion of the specified brush overlaps with the rearward end portion of the rearward commutator segment (a state in which the width of the specified brush and the width of the rearward commutator segment are just equal to each other), it holds that ripple angle θr=4pi. The ripple angle θr can be obtained by conversion from the mechanical angle θm.

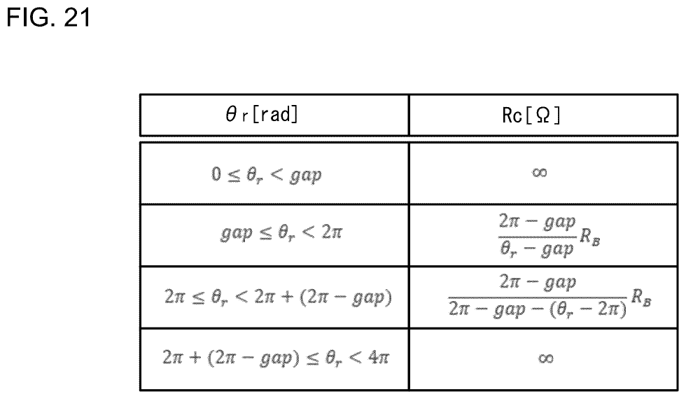

Based on the ripple angle θr, a contact resistance Rc between the specified brush and the specified commutator segment can be calculated as shown in a table of FIG. 21. It is noted that RB in FIG. 21 is equivalent to brush resistance R_B. Also, beyond the range of ripple angle θr shown in FIG. 21, the contact resistance value becomes ∞. However, as described before, when a calculated contact resistance Rc exceeds a saturation value Sat, it is set that the contact resistance Rc=Sat.

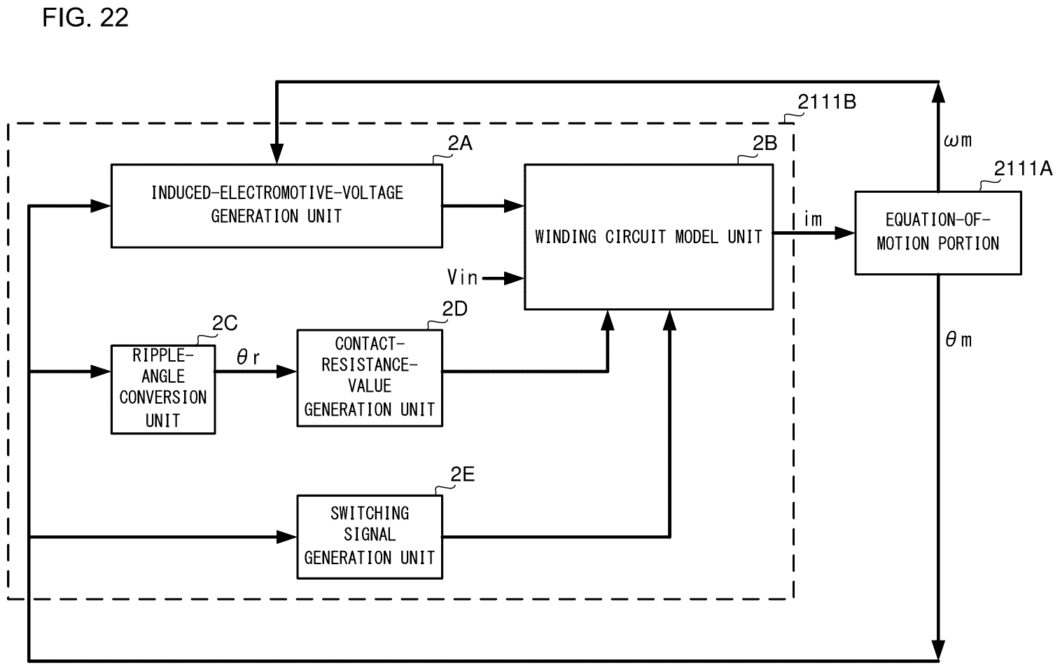

FIG. 22 is a diagram showing a configuration of the motor physical model 211 in a case where modeling is executed by Simscape (trademark)/Simulink (trademark).

The equation-of-motion portion 2111A, upon receiving a motor terminal current im outputted from the winding circuit portion 2111B, outputs a mechanical angle θm and a mechanical-angle angular velocity ωm to give feedback to the winding circuit portion 2111B.

The winding circuit portion 2111B includes an induced-electromotive-voltage generation unit 2A, a winding circuit model unit 2B, a ripple-angle conversion unit 2C, a contact-resistance-value generation unit 2D, a switching signal generation unit 2E.

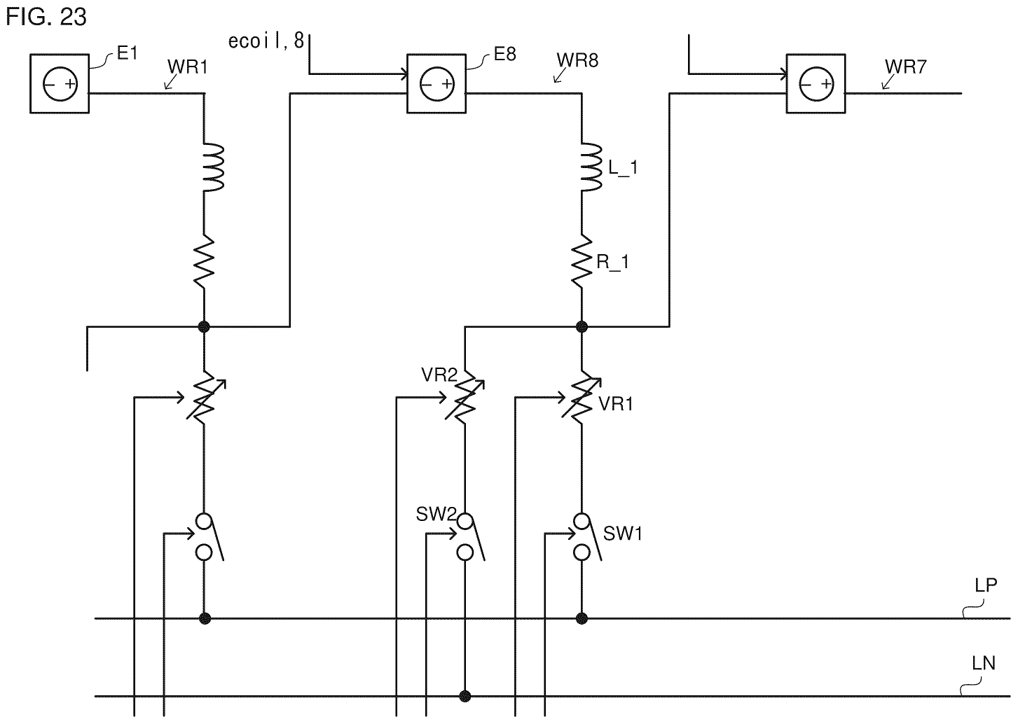

The induced-electromotive-voltage generation unit 2A, based on a mechanical angle θm, generates induced electromotive voltages for the windings WR, respectively. With regard to one example of the winding circuit model unit 2B, a partial configuration is shown in FIG. 23. In this case, with consideration given to the pole pair number p=2, eight windings WR, which is a half of the real-total-number sixteen windings WR, are subjected to modeling. In addition, windings WR counting the real total number may also be subjected to modeling.

Accordingly, as shown in FIG. 23, the windings WR are subjected to modeling with use of the windings WR1 to WR8, and the brush BR is subjected to modeling with use of one pair of anode brush and cathode brush. An induced electromotive voltage e_{coil,No.} generated by the induced-electromotive-voltage generation unit 2A is outputted from a voltage source E which is inserted in a winding WR of a corresponding winding number. FIG. 23 shows a case in which the induced electromotive voltage e_{coil,8} is outputted from the voltage source E8 in the winding WR8. Also, as shown in FIG. 23, the winding circuit model unit 2B is modeled in such fashion that switches SW1, SW2 and variable resistors VR1, VR2 are provided for each winding WR. In more detail, in a winding WR, an inductor L_1 and a resistor R_1 are connected in series, where one end (on one side opposite to the side of connection to the inductor L_1) of the resistor R_1 is connected to one end of the variable resistor VR1, and the switch SW1 is connected between the other end of the variable resistor VR1 and the anode line LP. The anode line LP is connected to the anode brush. Also, the one end of the resistor R_1 is connected also to one end of the variable resistor VR2, and the switch SW2 is connected between the other end of the variable resistor VR2 and a cathode line LN. The cathode line LN is connected to the cathode brush.

In a case where commutator segments CM to which lead wires of a winding WR are connected are put into contact with the anode brush, the switch SW1 is set to on status, and a resistance value of the variable resistor VR1 is set to the contact resistance value. When a commutator segment CM to which a lead wire of the winding WR is connected comes into contact with the cathode brush, the switch SW2 is set to on status, and the resistance value of the variable resistor VR2 is set to the contact resistance value. In addition, when the commutator segments CM and the anode brush or the cathode brush are out of contact with each other, the switch SW1 or the switch SW2 is set to off state. In addition, in some cases, both switches SW1, SW2 may be at off state.

The switching signal generation unit 2E shown in FIG. 22, based on the mechanical angle θm, determines on/off status of the switches SW1, SW2 for each of the windings WR to generate a switching signal. Based on the generated switching signal, the switches SW1, SW2 are set to on status or off status. Also, the ripple-angle conversion unit 2C converts a mechanical angle θm into a ripple angle θr. The contact-resistance-value generation unit 2D, based on the ripple angle θr, generates contact resistance values between the commutator segments CM and the brush BR. The generated contact resistance values are set as resistance values of the variable resistors VR1, VR2, respectively.

Under a condition that the induced electromotive voltage by the voltage source E, the on/off statuses of the switches SW1, SW2, and the resistance values of the variable resistors VR1, VR2 have been determined, the winding circuit model unit 2B calculates and outputs a motor terminal current im in response to input of an input voltage Vin. In addition, in a case where modeling is executed with eight windings WR in consideration of the above-described pole pair number=2, the motor terminal current im is diminished to one half, so that a calculated motor terminal current im is inputted to an amplifier having a gain of a double, followed by its output to the equation-of-motion portion 2111A.

### <Simulation Results>

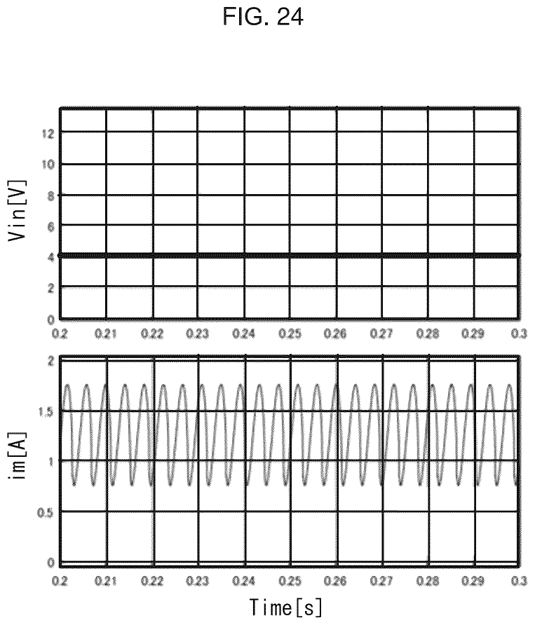

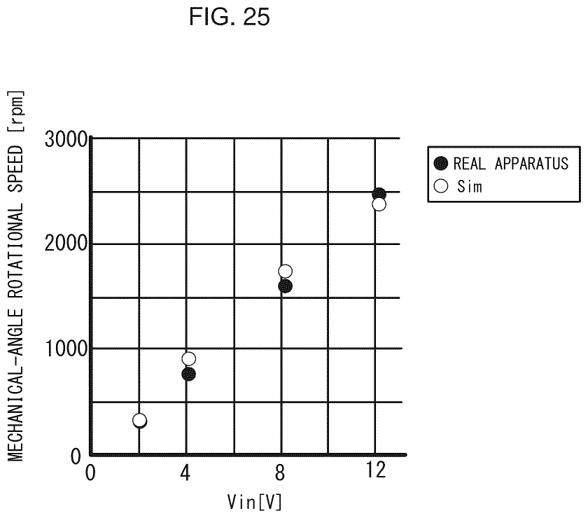

FIG. 24 is a chart showing one example of a simulation result in a case where a simulation according to the present disclosure was executed. There has arisen a ripple waveform in the motor terminal current im in response to application of an input voltage Vin, as with a real apparatus. Also, FIG. 25 is a chart showing one example in which the relationship between the input voltage Vin and the mechanical-angle rotational speed was compared between a real apparatus and a simulation. Thus, by the simulation, there has been reproduced a phenomenon, similar to the real-apparatus case, in which the mechanical-angle rotational speed was increased with increasing input voltage Vin. With the simulation according to the present disclosure, it is implementable to suppress calculation quantities to a large extent and reduce the simulation time.

### <Others>

In addition, various technical features disclosed herein may be carried out not only as in the above-described embodiment but also as changed or modified without departing from the gist of the technical creation of the disclosure. That is, the embodiment should be construed as not being limitative but being an exemplification at all points. The scope of the disclosure is defined not by the above description of the embodiment but by the appended claims, including all changes and modifications equivalent in sense and range to the claims.

### <Appendices>

As described hereinabove, a simulation apparatus (1) according to one aspect of the present disclosure includes:
a model storage unit (2) in which a motor physical model (211) derived from modeling of a brushed motor (20) has been stored; and
a model computing unit (3) configured to execute computing process by using the motor physical model, wherein
the motor physical model includes a winding circuit portion (2111B) derived from modeling of permanent magnets (Mg), windings (WR), commutator segments (CM) connected to the windings, and brushes (BR) contactable with the commutator segments, all of which are of the brushed motor (first configuration).

Also, in the first configuration, the winding circuit portion may allow a mechanical angle (θm) of a rotor (20B) including the windings and the commutator segments to be inputted thereto, and it may be implementable to reproduce sequential variations of contact state between the commutator segments and the brushes in response to the mechanical angle (second configuration).

Also, in the second configuration, the winding circuit portion may include a contact-resistance-value generation unit (2D) configured to calculate a contact resistance value (Rc) between the commutator segments and the brushes on a basis of the mechanical angle (third configuration).

Also, in the third configuration, the winding circuit portion may include a conversion unit (2C) configured to convert, from the mechanical angle, angular information (Or) representing a relative position of the commutator segments versus the brushes, and the contact-resistance-value generation unit may calculate the contact resistance value on a basis of the angular information (fourth configuration).

Also, in the fourth configuration, the contact-resistance-value generation unit may calculate the contact resistance value on bases of a contact resistance value (R_B) resulting under a condition that a width of each of the commutator segments and a width of each of the brushes are just equal to each other, a distance (gap) of a gap between neighboring ones of the commutator segments, and the angular information (fifth configuration).

Also, in the fifth configuration, an upper-limit value (Sat) intended for restriction of the calculated contact resistance value may be settable (sixth configuration).

Also, in any one of the third to sixth configurations, the winding circuit portion may include:
a first variable resistor (VR1) and a first switch (SW1) connected between the windings and the anode brush;
a second variable resistor (VR2) and a second switch (SW2) connected between the windings and the cathode brush; and
a switching signal generation unit (2E) configured to generate a switching signal for on/off switchover of the first switch and the second switch on a basis of the mechanical angle, and
the contact resistance values generated by the contact-resistance-value generation unit may be set as resistance values of the first variable resistor and the second variable resistor, respectively (seventh configuration).

Also, in any one of the first to seventh configurations, the winding circuit portion may include an induced-electromotive-voltage generation unit (2A) configured to calculate an induced electromotive voltage generated at the windings on bases of a mechanical angle and a mechanical-angle angular velocity (om) of a rotor including the windings and the commutator segments (eighth configuration).

Also, in the eighth configuration, the winding circuit portion may be modeled in such fashion that a voltage source (E) inserted in series to an inductor (L_1) and a resistor (R_1) of the windings outputs the induced electromotive voltage (ninth configuration).

Also, in the eighth or ninth configuration, a magnetic flux density distribution (B) by the permanent magnets in response to the mechanical angle may be settable, and the induced-electromotive-voltage generation unit may calculate the induced electromotive voltage on a basis of the magnetic flux density distribution (tenth configuration).

Also, in the tenth configuration, setting of the magnetic flux density distribution may be achieved by setting of maximum magnetic flux densities (Bm) corresponding to N poles and S poles, respectively, and setting of a variation method of magnetic flux density between the N poles and the S poles (eleventh configuration).

Also, in the tenth or eleventh configuration, a displacement (Sgap) of relative positional relationship between the permanent magnets and the brushes may be settable, and
a reference position of the magnetic flux density distribution may be varied in response to the displacement (twelfth configuration).

Also, in any one of the first to twelfth configurations, the winding circuit portion may be modeled while including
a capacitor (C0) connected between a motor anode terminal (Tp) and a motor cathode terminal (Tn), and
inductors (L0) connected between the motor anode terminal and the anode brush and between the motor cathode terminal and the cathode brush, respectively (thirteenth configuration).

Also, in any one of the first to thirteenth configurations, the motor physical model may include an equation-of-motion portion (2111A) for rotation, and
the winding circuit portion may allow an input voltage (Vin) applied to between the motor terminals, a mechanical angle of a rotor including the windings and the commutator segments, and a mechanical-angle angular velocity of the rotor to be inputted thereto,
the winding circuit portion may be enabled to output a motor terminal current (im) flowing through the motor terminals,
the equation-of-motion portion may be enabled to calculate a motor torque (Tm) on a basis of the motor terminal current and to calculate the mechanical-angle angular velocity and the mechanical angle on a basis of the motor torque, and
the mechanical angle and the mechanical-angle angular velocity outputted from the equation-of-motion portion may be fed back to the winding circuit portion (fourteenth configuration).

Further, a program according to one aspect of the disclosure is a program configured to allow a computer to function as the simulation apparatus according to any one of the first to fourteenth configurations (fifteenth configuration).

Further, a simulation method according to one aspect of the disclosure is a simulation method in which a computer executes computing process with use of a motor physical model including a winding circuit portion derived from modeling of permanent magnets, windings, commutator segments connected to the windings, and brushes contactable with the commutator segments, all of which are of a brushed motor (sixteenth configuration).

What is claimed is:

1. A simulation apparatus comprising:
a model storage unit in which a motor physical model derived from modeling of a brushed motor has been stored; and
a model computing unit configured to execute computing process by using the motor physical model,
wherein
the motor physical model includes a winding circuit portion derived from modeling of permanent magnets, windings, commutator segments connected to the windings, and brushes contactable with the commutator segments, all of which are of the brushed motor.

2. The simulation apparatus according to claim 1, wherein
the winding circuit portion allows a mechanical angle of a rotor including the windings and the commutator segments to be inputted thereto, and it is implementable to reproduce sequential variations of contact state between the commutator segments and the brushes in response to the mechanical angle.

3. The simulation apparatus according to claim 2, wherein
the winding circuit portion includes a contact-resistance-value generation unit configured to calculate a contact resistance value between the commutator segments and the brushes on a basis of the mechanical angle.

4. The simulation apparatus according to claim 3, wherein
the winding circuit portion includes a conversion unit configured to convert, from the mechanical angle, angular information representing a relative position of the commutator segments versus the brushes, and
the contact-resistance-value generation unit calculates the contact resistance value on a basis of the angular information.

5. The simulation apparatus according to claim 4, wherein
the contact-resistance-value generation unit calculates the contact resistance value on bases of a contact resistance value resulting under a condition that a width of each of the commutator segments and a width of each of the brushes are just equal to each other, a distance of a gap between neighboring ones of the commutator segments, and the angular information.

6. The simulation apparatus according to claim 5, wherein
an upper-limit value intended for restriction of the calculated contact resistance value is settable.

7. The simulation apparatus according to claim 3, wherein
the winding circuit portion includes:
a first variable resistor and a first switch connected between the windings and the anode brush;
a second variable resistor and a second switch connected between the windings and the cathode brush; and
a switching signal generation unit configured to generate a switching signal for on/off switchover of the first switch and the second switch based on the mechanical angle, and
the contact resistance values generated by the contact-resistance-value generation unit are set as resistance values of the first variable resistor and the second variable resistor, respectively.

8. The simulation apparatus according to claim 1, wherein
the winding circuit portion includes an induced-electromotive-voltage generation unit configured to calculate an induced electromotive voltage generated at the windings on bases of a mechanical angle and a mechanical-angle angular velocity of a rotor including the windings and the commutator segments.

9. The simulation apparatus according to claim 8, wherein
the winding circuit portion is modeled in such fashion that a voltage source inserted in series to an inductor and a resistor of the windings outputs the induced electromotive voltage.

10. The simulation apparatus according to claim 8, wherein
a magnetic flux density distribution by the permanent magnets in response to the mechanical angle is settable, and
the induced-electromotive-voltage generation unit calculates the induced electromotive voltage on a basis of the magnetic flux density distribution.

11. The simulation apparatus according to claim 10, wherein
setting of the magnetic flux density distribution is achieved by setting of maximum magnetic flux densities corresponding to N poles and S poles, respectively, and setting of a variation method of magnetic flux density between the N poles and the S poles.

12. The simulation apparatus according to claim 10, wherein
a displacement of relative positional relationship between the permanent magnets and the brushes is settable, and
a reference position of the magnetic flux density distribution is varied in response to the displacement.

13. The simulation apparatus according to claim 1, wherein
the winding circuit portion is modeled while including
a capacitor connected between a motor anode terminal and a motor cathode terminal, and inductors connected between the motor anode terminal and the anode brush and between the motor cathode terminal and the cathode brush, respectively.

14. The simulation apparatus according to claim 1, wherein
the motor physical model includes an equation-of-motion portion for rotation,
the winding circuit portion allows an input voltage applied to between the motor terminals,
a mechanical angle of a rotor including the windings and the commutator segments, and a mechanical-angle angular velocity of the rotor to be inputted thereto,
the winding circuit portion is enabled to output a motor terminal current flowing through the motor terminals,
the equation-of-motion portion is enabled to calculate a motor torque on a basis of the motor terminal current and to calculate the mechanical-angle angular velocity and the mechanical angle on a basis of the motor torque, and
the mechanical angle and the mechanical-angle angular velocity outputted from the equation-of-motion portion are fed back to the winding circuit portion.

15. A program configured to allow a computer to function as the simulation apparatus as claimed in claim 1.

16. A simulation method in which a computer executes computing process with use of a motor physical model including a winding circuit portion derived from modeling of permanent magnets, windings, commutator segments connected to the windings, and brushes contactable with the commutator segments, all of which are of a brushed motor.
